(19) United States
(12) Patent Application Publication
(10) Pub. No.: US 2023/0152689 A1
(43) Pub. Date: May 18, 2023

(54) WIRE GRID POLARIZER AND MANUFACTURING METHOD THEREOF

(71) Applicant: AIMCORE TECHNOLOGY CO., LTD., Hsinchu County (TW)

(72) Inventor: Chwei-Jing YEH, Hsinchu County (TW)

(21) Appl. No.: 17/526,403

(22) Filed: Nov. 15, 2021

(51) Int. Cl. G03F 7/00; G02B 5/30; B29D 11/00; G03F 7/16

(52) U.S. Cl. CPC G03F 7/0005; G02B 5/3058; B29D 11/00644; G03F 7/164; B29D 11/00865

(57) ABSTRACT

The invention provides a wire grid polarizer and a manufacturing method thereof. The method comprising steps of providing a substrate, forming a conductive layer on the substrate, forming an inverted wire grid structure on the conductive layer by nano-imprint or lithography process, and depositing a metal on the inverted wire grid structure to form a wire grid structure by electroforming or electrodeless coating technology. The conductive layer is transparent to the light wave band of the application. Since the method is an additive process, nano-imprint electroplating, electroforming, or electrodeless coating technology can be used, and the steps are simplified compared with subtractive process. Thus, the invention reduces or eliminates the need for expensive lithography technology, and avoids the use of complicated dry etching process.

### FIELD OF THE INVENTION

The invention relates to a method for manufacturing a wire grid polarizer, and more particularly to a manufacturing method for a wire grid polarizer with an additive process by nanoimprinting, electroforming, or electrodeless plating technology.

### BACKGROUND OF THE INVENTION

Wire grid polarizer (WGP) has better extinguish ratio and view angle than traditional polarizers. General polarizers containing plastic materials that are not resistant to high temperatures will reduce or lose their polarization performance at 100° C. Therefore, wire grid polarizer is more suitable to be applied to high-end display devices, projectors, light sensors, ambient light sensors (ALS), image detection, face recognition and gesture recognition, automotive Lidar imaging and range detection system, 3D face recognition system of Time of Flight (TOF).

The wire grid size of the wire grid polarizer is approximately ½˜⅕ of the wavelength of the applied light wave band. If the applied light wave band is the visible light wave band (400 nm˜700 nm), the pitch of the wire grid is approximately close to 100 nm, and the line width of the wire grid is about 50 nm; if the applied light wave band is in the ultraviolet (UV) range, the line width of the wire grid is below 20 nm. Therefore, the requirements for precision in production are very high.

The manufacturing methods of the conventional wire grid polarizer can be found in U.S. Pat. Nos. 10,353,127 B2, 10,983,389 B2, 10,114,161 B2, and 9,488,765 B2, wherein the wire grids need to be formed by a expensive lithography equipment, such as electron beam (e-beam), ion-beam, extreme ultraviolet (EUV), dual UV-Beam interference or X-Ray exposure sources. Accordingly, the manufacturing method of extremely fine and low defect density wire grids requires proceeding in high precision and being performed repeatedly, resulting in a high cost, and hard to be applicable.

### SUMMARY OF THE INVENTION

The invention provides a manufacturing method for a wire grid polarizer comprising following steps of: providing a substrate; forming a conductive layer on the substrate; forming an inverted wire grid structure on the conductive layer, wherein the inverted wire grid structure comprises a plurality of ridges and a plurality of trenches disposed alternately with the plurality of ridges, and the conductive layer is exposed at the plurality of trenches; and depositing a metal on the inverted wire grid structure formed on the conductive layer to form a wire grid structure; wherein the metal is deposited by an electroplating, an electroforming, or an electrodeless plating process.

The invention further provides a wire grid polarizer comprising: a substrate; a conductive layer formed on the substrate; and a wire grid structure formed on the conductive layer, wherein the wire grid structure is deposited on the conductive layer by an electroplating, an electroforming, or an electrodeless plating process.

### BRIEF DESCRIPTION OF THE DRAWINGS

FIG. 1A-1I are schematic diagrams of the steps of a manufacturing method according to a first embodiment of the invention.

FIG. 2 is a schematic diagram of a wire grid polarizer according to first embodiment of the invention.

FIG. 3 is a schematic diagram according to a second embodiment of the invention.

FIG. 4 is a schematic diagram according to a third embodiment of the invention.

FIG. 5 is a schematic diagram according to a fourth embodiment of the invention.

FIG. 6 is a schematic diagram according to a fifth embodiment of the invention.

FIG. 7 is a schematic diagram according to a sixth embodiment of the invention.

FIG. 8 is a schematic diagram according to a seventh embodiment of the invention.

FIG. 9 is a schematic diagram according to an eighth embodiment of the invention.

FIG. 10 is a schematic diagram according to a ninth embodiment of the invention.

### DETAILED DESCRIPTION OF THE PREFERRED EMBODIMENTS

The following description provides several different embodiments or examples to illustrate different features of the invention. The description provides specific examples of each component and its disposition mode, but these specific examples are not intended to limit the invention. For example, if it is described below that a first feature is formed on or above a second feature, it means that the first feature may directly contact with the second feature, or the first feature may not contact with the second feature since additional features are formed between the first feature and the second feature. In addition, the different embodiments described below may repeatedly use the same reference symbols and/or marks for the purpose of simplifying the description, but it is not used to limit the specific relationship between the different embodiments and/or structures.

In the specification, although some embodiments execute the steps in a specific order, the steps may be executed in another reasonable order. For different embodiments, certain features described below can be replaced or eliminated. It should be understood that some additional operations can be performed before, during, or after the method, and in other embodiments of the method, some operations can be replaced or omitted.

In this specification, the terms used in the description of various embodiments are only for the purpose of describing specific examples, and are not intended to limit the invention. Unless the context clearly indicates otherwise, or deliberately limits the quantity of elements, the singular forms “a”, “an” and “the” used herein also include plural forms.

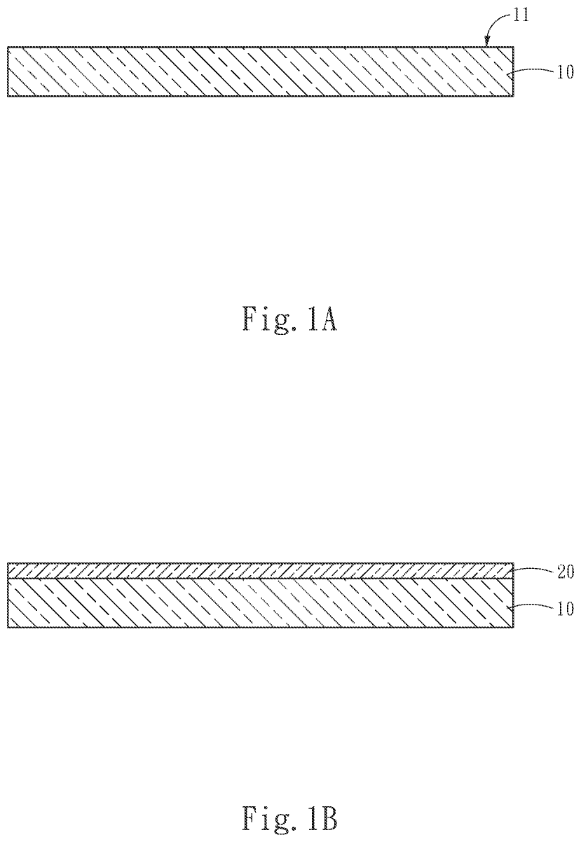

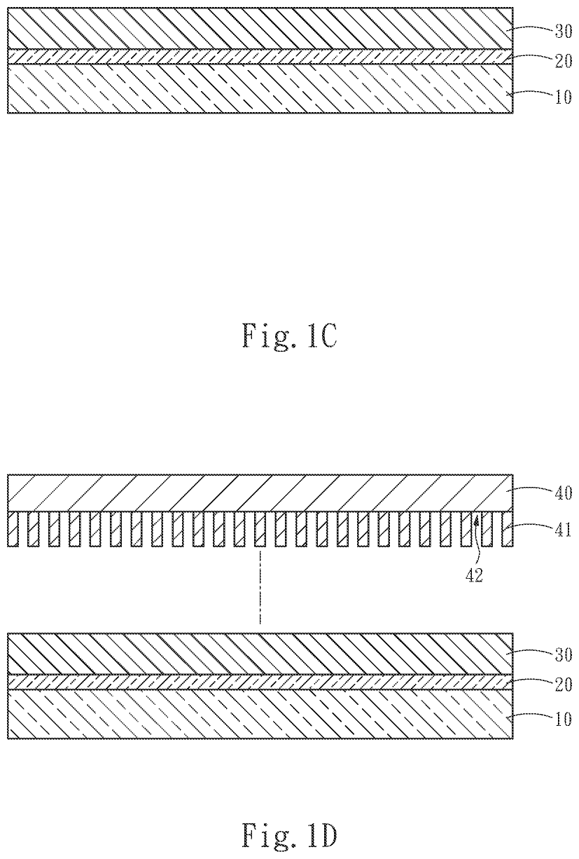

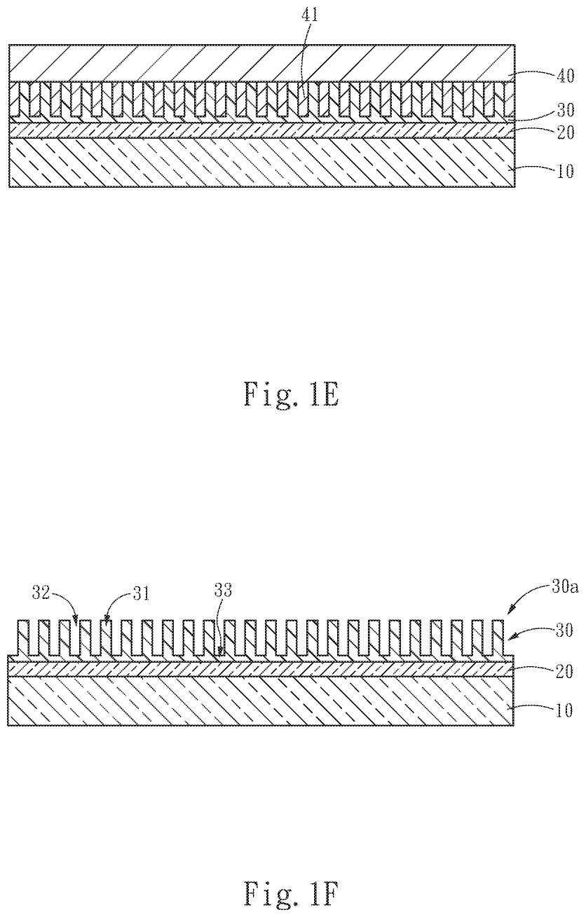

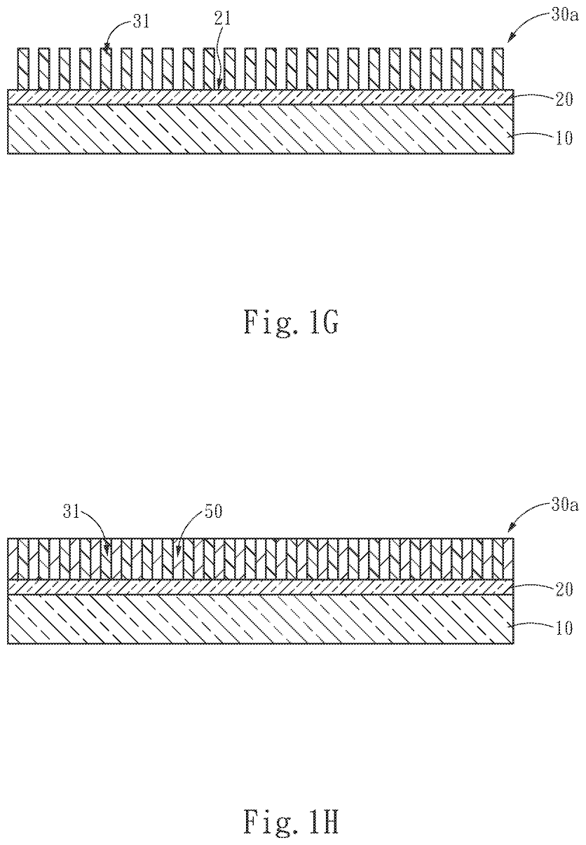

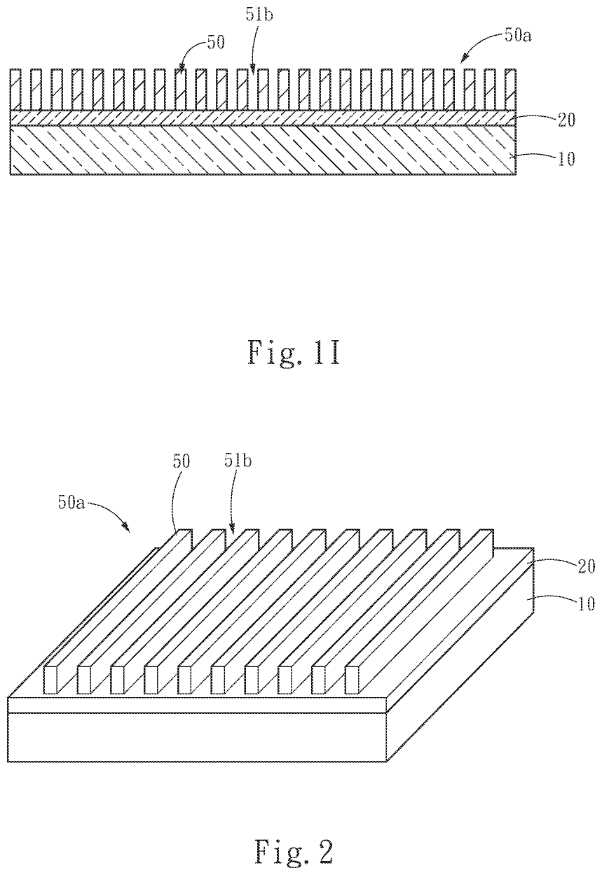

Please refer to FIG. 1A, FIG. 1B, FIG. 1C, FIG. 1D, FIG. 1E, FIG. 1F, FIG. 1G, FIG. 1H and FIG. 1I, which show the steps of a manufacturing method according to a first embodiment of the invention. As shown in FIG. 1A, a substrate 10 is first provided. In this embodiment, the substrate 10 is transparent to the light wave band of the application. If the substrate 10 is made of one of materials selected from quartz, optical glass (such as BK7 glass, soda glass, boron glass, alkali-free glass, aluminosilicate glass, borosilicate glass, but is not limited thereto), sapphire, silicon dioxide (SiO₂), silicon nitride (SiNₓ), aluminium oxide (Al₂O₃), zirconium dioxide (ZrO₂), aluminium nitride (AlNₓ), gallium nitride (GaN), gallium arsenide (GaAs) and indium phosphide (InP), the substrate 10 is transparent to ultraviolet, visible, near-infrared, infrared, far-infrared wave bands. If the substrate 10 is made of one of materials selected from silicon (Si) and silicon carbide (SiC), the substrate 10 is transparent to near-infrared, infrared and far-infrared wave bands. If the substrate 10 is made of one of materials selected from high molecular plastics (such as polycarbonate (PC), COP (Cyclo Olefin Polymer), polyimide (PI), polyethylene terephthalate (PET), triacetate (TAC), polyethylene naphthalate (PEN)), the substrate 10 is transparent to visible, near-infrared, infrared, and far-infrared wave bands. In addition, the substrate 10 can also be coated or bonded with thermal release adhesive or UV release adhesive to facilitate removal of the substrate 10 if necessary, or transfer of a component to another substrate or component to reduce an overall thickness of the component.

As shown in FIG. 1B, a conductive layer 20 is formed on an upper surface 11 of the substrate 10. The conductive layer 20 is used to form a wire grid structure. The conductive layer 20 is made of a metal material (thickness less than 100 nm), a metal oxide material (thickness less than 500 nm), or a non-oxide material (thickness less than 500 nm). For example, the metal material can be a pure metal such as gold (Au), silver (Ag), copper (Cu), nickel (Ni), aluminum (Al), platinum (Pt), or an alloy thereof. The metal oxide material can be tin dioxide (SnO₂), indium oxide (In₂O₃), cadmium oxide (CdO), zinc oxide (ZnO), titanium dioxide (TiO₂), a mixture (SnO₂—Sb) of tin dioxide and antimony, a mixture (SnO₂—WO₃) of tin dioxide and tungsten oxide, a mixture (In₂O₃—SnO₂, ITO) of indium oxide and tin oxide, a mixture (In₂O₃—ZnO, IZO) of indium oxide and zinc oxide, a mixture (In₂O₃—Sb₂O₃) of indium oxide and antimony oxide, a mixture (In₂O₃—WO₃) of indium oxide and tungsten oxide, a mixture (SnO₂—F) of tin dioxide and fluorine, a mixture (In₂O₃—Al) of indium oxide and aluminum, a mixture (ZnO—Al, AZO) of zinc oxide and aluminum, gallium zinc oxide (GaZnO, GZO), indium gallium zinc oxide (InGaZnO, IGZO) or a combination of at least two of the above-mentioned metal oxides. The non-oxide material of the conductive layer 20 can be lanthanum hexaboride (LaB₆), titanium nitride (TiN), cadmium sulfide (CdS).

To manufacture a transmission type wire grid polarizer, the substrate 10 and the conductive layer 20 should be made of a material which is transparent to the light wave band of the application. To manufacture a reflective wire grid polarizer, both the substrate 10 and the conductive layer 20 can be made of an opaque material. Alternatively, either the substrate 10 or the conductive layer 20 can be made of a material which is transparent to the light wave band of the application, and another is made of the opaque material.

In one embodiment, the conductive layer 20 is a single layer from any one of the metal, the metal oxide, and the non-oxide, and can also be a single layer, a double layer or a multilayer of a mixture from any two of the metal, the metal oxide, and the non-oxide or a mixture of the metal, the metal oxide, and the non-oxide, such as TiO₂/Ag/TiO₂, SnO₂/Ni/SnO₂, Bi₂O₃/Au/Bi₂O₃, Pt/SnO₂, SnO₂/Au/SnO₂.

Then, an inverted wire grid structure is formed on the conductive layer 20 to serve as a mold for forming the wire grid structure. In the invention, processes such as laser interference lithography, e-beam lithography, ion-beam lithography, extreme ultraviolet (EUV) lithography, X-ray lithography, photo-lithography, or nano-imprint lithography can be used to form the inverted wire grid structure, but the invention is not limited thereto. Among the lithography techniques listed above, the nano-imprint lithography has a lower production cost. Specifically, most of the lithography techniques require an electron beam lithography (EBL) equipment to form the inverted wire grid structure; however, the cost of the EBL equipment is high, and it takes a long manufacturing time for the EBL equipment to form the inverted wire grid structure on the large-area wire grid polarizer (for example, it takes about 3 to 4 days to manufacture on a single six-inch wafer). Thus, the lithography techniques implemented by the EBL equipment are disadvantageous for commercial applications since their mass production capacities are low. On the contrary, the nano-imprint lithography is able to form the inverted wire grid structure on a large-area nano-imprint resist layer by only one-time imprinting, thereby the nano-imprint lithography can be implemented by low cost equipment and has a rapid manufacturing time. Accordingly, the following steps of the invention for forming the inverted wire grid are illustrated by using the nano-imprint lithography.

As shown in FIG. 1C, a nano-imprint resist layer 30 is formed on the conductive layer 20. The nano-imprint resist layer 30 can be formed by spin coating or spray coating, but the invention is not limited thereto. The nano-imprint resist layer 30 can be made of a thermal curable polymer resin or a UV-curable polymer resin, such as acrylic-based or epoxy-based polymer material. In FIG. 1D, a nano-imprint lithography process is performed on the nano-imprint resist layer 30 by a stamp 40, and the stamp 40 is used as a transfer printing element and has a specific pattern which comprises a plurality of protrusions 41 and a plurality of recesses 42.

Further, the stamp 40 is imprinted on the nano-imprint resist layer 30 after being aligned therewith. As shown in FIG. 1E, the specific pattern is transferred onto the nano-imprint resist layer 30. The specific pattern of the stamp 40 corresponds to the wire grid structure. As shown in FIG. 1F, an inverted wire grid structure 30a is formed on the nano-imprint resist layer 30 after imprinting. The inverted wire grid structure 30a comprises a plurality of ridges 31 and a plurality of trenches 32, respectively extending in one direction (an axial direction into the paper as shown in FIG. 1F) to form a fin-like structure, and the plurality of ridges 31 and the plurality of trenches 32 are disposed in an alternative manner and are complementary to the wire grid structure. In this example, the nano-imprint resist layer 30 leaves a residual portion 33. Afterwards, as shown in FIG. 1G, the residual portion 33 can be removed by oxygen ashing (O₂Ashing) or inductively coupled plasma (ICP) through oxygen, but the invention is not limited thereto. An upper surface 21 of the conductive layer 20 is exposed between the plurality of ridges 31. A fabrication of the inverted wire grid structure 30a is completed so far.

As shown in FIG. 1H, a metal 50 is deposited on the inverted wire grid structure 30a on the conductive layer 20. A manufacturing process of deposition can be electroplating, electroforming or electrodeless plating (also called chemical-plating or autocatalytic plating). The metal 50 can be a metal element or an alloy, such as gold (Au), silver (Ag), copper (Cu), iron (Fe), chromium (Cr), zinc (Zn), nickel (Ni), aluminum (Al), titanium (Ti), tin (Sn), platinum (Pt), palladium (Pd), brass (alloy of copper and Zinc), nickel-gold 5 alloy, or nickel-boron alloy (NiB), but the invention is not limited thereto. The metal 50 is formed between the plurality of ridges 31 to form a wire grid structure 50a. Then, the inverted wire grid structure 30a can be removed by oxygen ashing (O₂Ashing) or inductively coupled plasma (ICP) through oxygen to obtain a wire grid polarizer, as shown in FIG. 1I and FIG. 2.

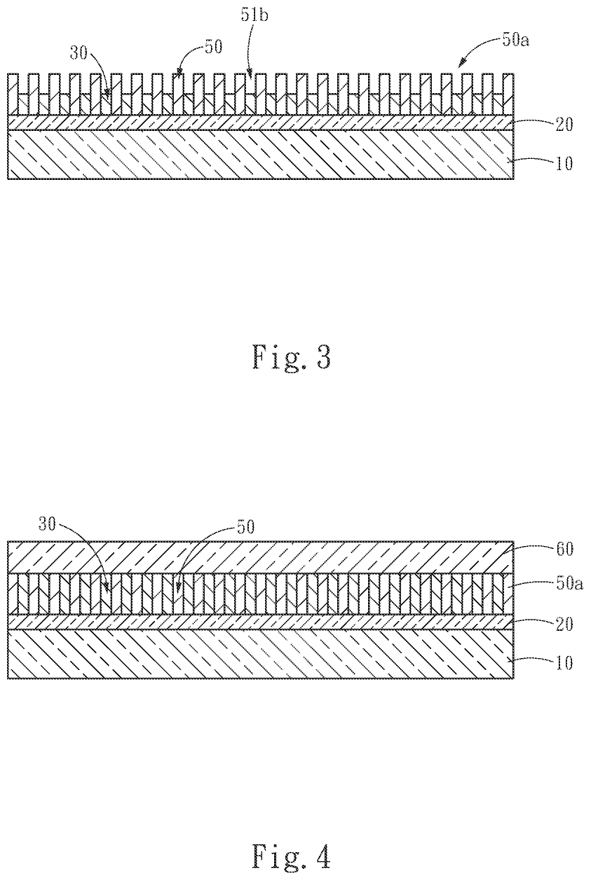

In order to improve the optical characteristics, reliability, and packaging structure of the wire grid polarizer, and the selection of materials is considered, the wire grid polarizer will comprise the following structures which will be illustrated by following examples, and the invention is not limited thereto. Please refer to FIG. 3 for a schematic diagram of a second embodiment of the invention. In this embodiment, after FIG. 1H, only part of the inverted grid structure 30a is removed, and other part of the nano-imprint resist layer 30 is remained. Please refer to FIG. 4 for a schematic diagram of a third embodiment of the invention. In this embodiment, after the step of FIG. 1H, the nano-imprint resist layer 30 is not removed, and an optical layer 60 is further formed on the wire grid structure 50a and the nano-imprint resist layer 30, the optical layer 60 is a sheet-like structure and is made of a material transparent to the light wave band of the application. The optical layer 60 can be an adhesive used in a packaging process, such as optically clear adhesive (OCA), bonding glue or resin, bonding film, hard coat film, optical adhesive film etc., but the invention is not limited thereto. The optical layer 60 can also be an optical coating made of silicon dioxide (SiO₂), silicon nitride (SiNₓ), or magnesium fluoride (MgF₂), or other similar materials. Alternatively, the optical layer 60 can also be made of the materials of the conductive layer 20 and/or the substrate 10 mentioned above. Thereby, the optical characteristics, reliability, and scratch resistance of the wire grid polarizer can be improved.

The optical layer 60 can also be an optical film with specific optical characteristics formed on the wire grid structure 50a and the nano-imprint resist layer 30 by coating or bonding to improve or adjust the optical characteristics of the wire grid polarizer. The optical layer 60 can be, for example, band-pass filter, band-stop filter, low-pass filter, high-Pass filter, anti-reflection coating or RGB filter to improve the transmittance and reflectance of a specific wavelength range.

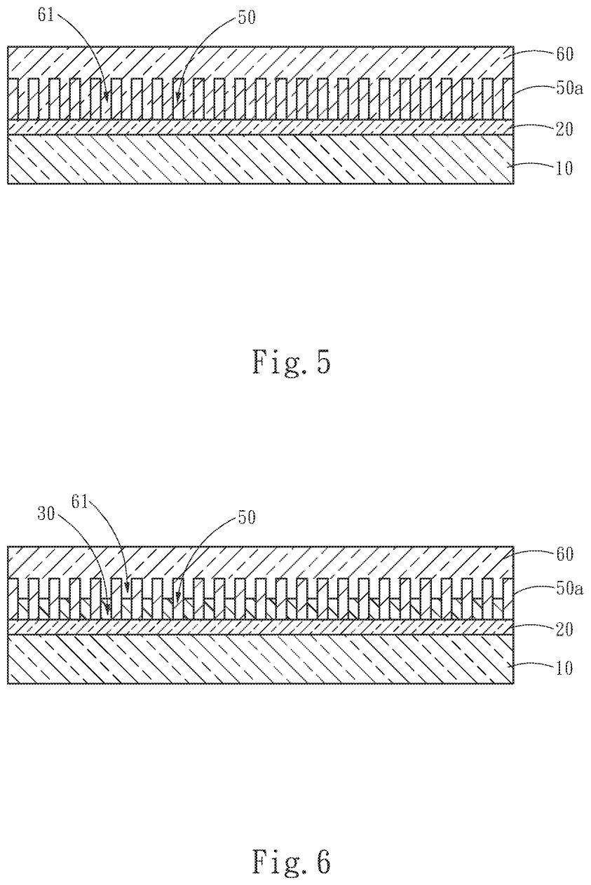

Please refer to FIG. 5 for a schematic diagram of a fourth embodiment of the invention. In this embodiment, after the step of FIG. 1I, the optical layer 60 is further formed on the wire grid structure 50a, and the optical layer 60 comprises a columnar structure 61 filling a recess 50b of the wire grid structure 50a. The optical layer 60 can be silicon dioxide (SiO₂), silicon nitride (SiNₓ), magnesium fluoride (MgF₂), zirconium dioxide (ZrO₂), or other materials. The optical layer 60 can also be a transparent adhesive for bonding used in the general component packaging process, such as optically clear adhesive (OCA), protective adhesive, hard coat film, bonding glue or resin, or photoresist, imprint resin, but is not limited thereto. Adding the optical layer 60 can be a requirement for component packaging, or can be used to improve the optical characteristics, reliability, and scratch resistance of the metal optical grating.

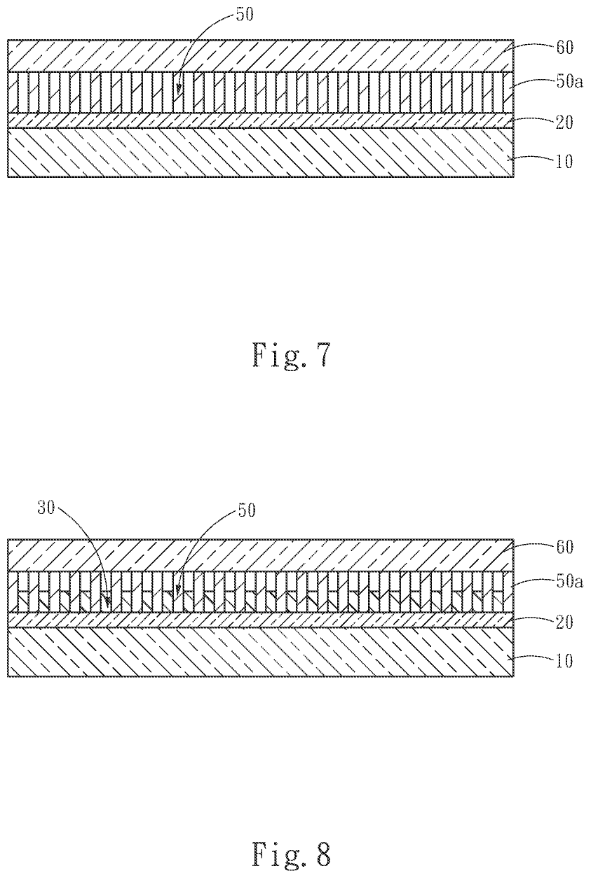

Please refer to FIG. 6 for a schematic diagram of a fifth embodiment of the invention. In this embodiment, after the step of FIG. 1H, only part of the inverted wire grid structure 30a is removed, remaining part of the nano-imprint resist layer 30, and the optical layer 60 is further formed on the wire grid structure 50a. The columnar structure 61 of the optical layer 60 fills in the recess 50b of the wire grid structure 50a and is formed on the nano-imprint resist layer 30. Please refer to FIG. 7 for a schematic diagram of a sixth embodiment of the invention. In this embodiment, after the step of FIG. 1I, the optical layer 60 is further formed on the wire grid structure 50a, the optical layer 60 is a sheet-like structure, and no material is filled between the metal 50. Please refer to FIG. 8 for a schematic diagram of a seventh embodiment of the invention. In this embodiment, after the step of FIG. 1H, only part of the inverted wire grid structure 30a is removed, remaining part of the nano-imprint resist layer 30, and the optical layer 60 is further formed on the wire grid structure 50a. The optical layer 60 is a sheet-like structure.

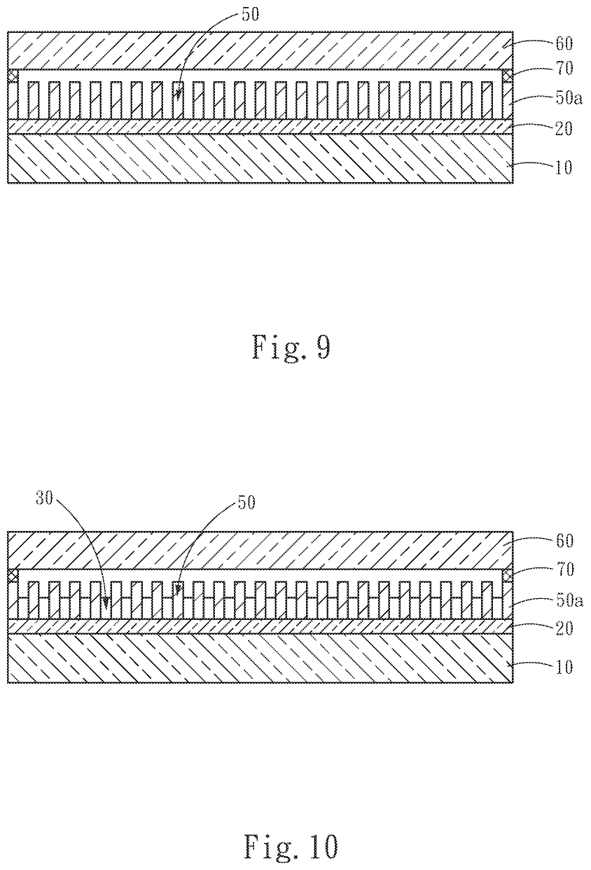

Please refer to FIG. 9 for a schematic diagram of an eighth embodiment of the invention. In this embodiment, after the step of FIG. 1I, the optical layer 60 is disposed on the wire grid structure 50a through a bonding layer 70. The bonding layer 70 can be an opaque material for packaging, or a low melting metal or alloy for packaging with different substrate materials, such as aluminum (Al), tin (Sb), indium (In), tin gold (AuSb) etc., but the invention is not limited thereto. A material of the bonding layer 70 needs to be matched with the materials of the optical layer 60 and the wire grid structure 50a. A method of forming the bonding layer 70 is a conventional technology of packaging process, thus it will not be mentioned here again. Please refer to FIG. 10 for a schematic diagram of a ninth embodiment of the invention. In this embodiment, after the step of FIG. 1H, only part of the inverted wire grid structure 30a is removed, remaining part of the nano-imprint resist layer 30, and the optical layer 60 is disposed on the wire grid structure 50a through the bonding layer 70.

The optical layer 60 is disposed to match with the wire grid structure 50a according to different applications. In addition to the positions shown in the figures, in other embodiments, forming at least one optical layer 60 on the substrate 10, and the conductive layer 20 is formed on the optical layer 60, the nano-imprint resist layer 30 is then formed on the conductive layer 20, and the above-mentioned steps are performed to obtain the wire grid structure 50a.

In the invention, a conductive layer formed on a substrate is used to form an inverted wire grid structure through nano-imprint lithography or other lithography techniques. By utilizing an electric conductivity of the conductive layer, electroplating, electroforming or electrodeless coating can be used to form a wire grid polarizer on the conductive layer, thereby reducing or eliminating the need to use lithography technology and photomask to form a wire grid, and also eliminating the complicated dry etching inductively coupled plasma (ICP) process, making the manufacturing process procedure cheaper and simpler; secondly, after the inverted wire grid structure is formed, the metal is directly deposited to form a wire grid structure, which is an additive process to simplify the production procedure to be capable of greatly reducing the production cost.

What is claimed is:

1. A manufacturing method for a wire grid polarizer, comprising following steps of:
providing a substrate;
forming a conductive layer on the substrate;
forming an inverted wire grid structure on the conductive layer, wherein the inverted wire grid structure comprises a plurality of ridges and a plurality of trenches which are disposed in an alternative manner, and the conductive layer is exposed at the plurality of trenches; and
depositing a metal on the inverted wire grid structure formed on the conductive layer to form a wire grid structure;
wherein the metal is deposited by an electroplating, an electroforming, or an electrodeless plating process.

2. The manufacturing method as claimed in claim 1, wherein the inverted wire grid structure is formed by a laser interference lithography, an e-beam lithography, an ion-beam lithography, an extreme ultraviolet lithography, a X-ray lithography, a photo-lithography, or a nano-imprint lithography.

3. The manufacturing method as claimed in claim 1, wherein the inverted wire grid structure is formed by following steps of:
forming a nano-imprint resist layer on the conductive layer; and
performing a nano-imprint lithography process on the nano-imprint resist layer by a stamp to form the inverted wire grid structure on the conductive layer.

4. The manufacturing method as claimed in claim 1, wherein after depositing the metal, the manufacturing method further comprises a step of removing all the inverted wire grid structure.

5. The manufacturing method as claimed in claim 4, wherein after removing the inverted wire grid structure, the manufacturing method further comprises a step of forming an optical layer on the wire grid structure.

6. The manufacturing method as claimed in claim 4, wherein after removing the inverted wire grid structure, the manufacturing method further comprises steps of forming a bonding layer on the wire grid structure, and forming an optical layer on the bonding layer.

7. The manufacturing method as claimed in claim 4, wherein before forming the conductive layer, the manufacturing method further comprises steps of forming at least one optical layer, and forming the conductive layer on the optical layer.

8. The manufacturing method as claimed in claim 1, wherein after depositing the metal, the manufacturing method further comprises a step of removing part of the inverted wire grid structure to remain a residual portion.

9. The manufacturing method as claimed in claim 8, wherein after removing the inverted wire grid structure, the manufacturing method further comprises a step of forming an optical layer on the wire grid structure.

10. The manufacturing method as claimed in claim 8, wherein after removing the inverted wire grid structure, the manufacturing method further comprises steps of forming a bonding layer on the wire grid structure, and forming an optical layer on the bonding layer.

11. The manufacturing method as claimed in claim 8, wherein before forming the conductive layer, the manufacturing method further comprises steps of forming at least one optical layer, and forming the conductive layer on the optical layer.

12. The manufacturing method as claimed in claim 1, wherein the conductive layer is made of a metal material, a metal oxide material, or a non-oxide material.

13. The manufacturing method as claimed in claim 12, wherein the metal material is gold (Au), silver (Ag), copper (Cu), nickel (Ni), aluminum (Al), platinum (Pt), or a combination thereof.

14. The manufacturing method as claimed in claim 12, wherein the metal oxide material is tin dioxide (SnO₂), indium oxide (In₂O₃), cadmium oxide (CdO), zinc oxide (ZnO), titanium dioxide (TiO₂), a mixture (SnO₂—Sb) of tin dioxide and antimony, a mixture (SnO₂—WO₃) of tin dioxide and tungsten oxide, a mixture (In₂O₃—SnO₂) of indium oxide and tin oxide, a mixture (In₂O₃—ZnO) of indium oxide and zinc oxide, a mixture (In₂O₃—Sb₂O₃) of indium oxide and antimony oxide, a mixture (In₂O₃—WO₃) of indium oxide and tungsten oxide, a mixture (SnO₂—F) of tin dioxide and fluorine, a mixture (In₂O₃—Al) of indium oxide and aluminum, a mixture (ZnO—Al) of zinc oxide and aluminum, gallium zinc oxide (GaZnO), indium gallium zinc oxide (InGaZnO), or a combination thereof.

15. The manufacturing method as claimed in claim 12, wherein the non-oxide material is lanthanum hexaboride (LaB₆), titanium nitride (TiN), or cadmium sulfide (CdS).

16. A wire grid polarizer, comprising:
a substrate;
a conductive layer formed on the substrate; and
a wire grid structure formed on the conductive layer, wherein the wire grid structure is deposited on the conductive layer by an electroplating, an electroforming, or an electrodeless plating process.
